(19) United States
(12) Patent Application Publication
(10) Pub. No.: US 2005/0269689 A1
(43) Pub. Date: Dec. 8, 2005

(54) Conductor device and method of manufacturing thereof

(75) Inventor: Takashi Tetsuka, Kanagawa (JP)

Correspondence Address: FOLEY AND LARDNER;SUITE 500, 3000 K STREET NW, WASHINGTON, DC, 20007, US

(73) Assignee: NEC Electronics Corporation

(21) Appl. No.: 11/142,280

(22) Filed: Jun. 2, 2005

(30) Foreign Application Priority Data
Jun. 3, 2004 (JP) 2004/165604

(51) Int. Cl. H01L 23/10

(52) U.S. Cl. 257/706

(57) ABSTRACT

A semiconductor device has a package substrate, and a heat spreader having a first surface attached to the package substrate. The heat spreader has a lattice-shaped slit opening on at least the first surface.

### BACKGROUND OF THE INVENTION

1. Field of the Invention

The present invention relates to a technique for lowering thermal resistance of a semiconductor package.

2. Description of the Related Art

With the rapid diffusion of the Internet, intranets, and the like in these days, semiconductor devices used in these network systems have been made compact, high-power, and to have multi-pins. In connection to the above-described features, lowering the thermal resistance of the semiconductor device is progressed in order to improve reliability of the semiconductor device.

As a method for lowering the thermal resistance of a semiconductor package, it is well known for the public that a heat spreader is provided on a surface of the semiconductor package. Referring to FIG. 1, a heat spreader 101 is attached to a surface of a package substrate 103 in which a semiconductor chip 104 is accommodated. Heat of the surface of the semiconductor package is radiated by the heat spreader 101 having a good thermal conductivity.

To manufacture the semiconductor device, it is necessary to attach the heat spreader 101 to the package substrate 103 on which external terminals 105 are formed. As to the attachment, a thin adhesive sheet (not shown) is used. Since the adhesive sheet is thin, it is first attached to either the package substrate 103 or the heat spreader 101. Next, in order to melt the adhesive sheet, the adhesive sheet is heated together with the package substrate 103 or the heat spreader 101 to which it is attached. If only one of the package substrate 103 and the heat spreader 101 is heated, the heat is immediately drawn from the heated one to unheated one when both the package substrate 103 and the heat spreader 101 are attached to each other. Therefore, the package substrate 103 or the heat spreader 101 to which the adhesive sheet is not attached is also heated. The package substrate 103 and the heat spreader 101 are attached to each other with the adhesive sheet which is melted due to the above heat treatment. Both of them are thermally expanded due to the heat treatment.

As the package substrate 103 and the heat spreader 101 are cooled down after the heat treatment, each of them shrinks to restore its original size. However, since the thermal expansion coefficient of the package substrate 103 is different from that of the heat spreader 101, there is a large difference in the amount of the thermal expansion between the package substrate 103 and the heat spreader 101. Thus, a large difference in the amount of contraction appears between the package substrate 103 and the heat spreader 101, when their temperatures return to the room temperature. Stresses are produced due to the difference in the amount of contraction, which causes warpage of the semiconductor package. Furthermore, even after the semiconductor device is manufactured, the warpage changes with time due to residual stress and increases up to a certain amount. A multi-pin package with a large size tends to be employed in recent years, and the warpage of such a multi-pin package is large in particular.

Japanese Laid Open Patent Application No. 2002-184914 discloses a compound semiconductor device. A slit is disposed between insulating boards which are adjacently placed and fixed on the heat sink used in the compound semiconductor device. Stress at the time of basing and at the time of a secular change is relieved with the formation of the slit. Warp quantity is relatively reduced, the crack of the insulating board is prevented and mechanical stress given to a semiconductor pellet can be reduced.

Japanese Laid Open Patent Application No. 2003-60137 discloses a substrate for module. The substrate for a module includes a heat sink and an insulative substrate that is provided with a conductor circuit on one main plane. The heat sink holds an area for mounting directly a semiconductor element through a joint layer. The insulative substrate is divided into two or more and provided in an area including a portion where at least the conductor circuit is formed. The insulative substrate is jointed with the heat sink through an adhesive layer. The heat sink is made of metal or alloy whose thermal conductivity is 100 W/mK or higher. A roughened surface is provided on the boundary surface between the joint layer and the adhesive layer.

Japanese Laid Open Patent Application No. Sho-56-161662 discloses a semiconductor device. In the semiconductor device, a semiconductor element is mounted on an insulative board. A member is fixed to a surface of the insulative board facing the semiconductor element. Thermal expansion coefficient of the member is substantially the same as that of the insulative board. Also, thermal conductivity of the member is larger than that of the insulative board.

Japanese Laid Open Patent Application No. Hei-3-101257 discloses a semiconductor device. A heat sink is attached to a surface of a package by an adhesive agent. A concave portion is provided on the adhesion surface of the heat sink. The adhesion surface is divided into a plurality of surfaces.

Japanese Laid Open Patent Application No. Hei-6-169037 discloses a semiconductor package. A semiconductor chip is mounted on a header which is formed integrally with a heat sink of a semiconductor package. Grooves are provided in the chip mounting surface of the header outside the region where the chip is mounted. Also, a rectangular groove is provided in the back surface of the heat sink. With these grooves, the bending of the heat sink and the bending of the header are suppressed. Thus, cracks in the chip or in the mounting components are prevented.

Japanese Laid Open Patent Application No. Hei-10-340970 discloses a BGA semiconductor device. On a surface of a heat dissipating plate to which a semiconductor chip is fixed, a stiffener is attached by using an adhesive agent. A flexible tape is attached to the stiffener with an adhesive agent. The semiconductor chip is electrically connected with a solder bump via an inner lead and a land which are formed on the tape. Trenches which open to the outer peripheral end of the stiffener are formed on the attachment surface of the stiffener.

Japanese Laid Open Patent Application No. Hei-8-186203 (referred to as a “patent publication” hereinafter) discloses a heat spreader for a semiconductor device. In the heat spreader, a stripe-like metallic body is formed wherein Fe—Ni alloy and Cu metal are laminated alternately and arranged in a stripe shape along one direction within a chip mounting surface. The Fe—Ni alloy and Cu metal penetrate from the chip mounting surface to the opposite surface. It is also shown in FIG. 11 and the paragraph 0029 of the patent publication that the heat spreader is employed in a cavity down type semiconductor device having a ceramic package. Furthermore, it is described in the paragraph 0048 that thermal distortions in soldering and die bonding can be solved also in the ceramic package because the thermal expansion coefficient of the heat spreader is consistent with that of ceramic.

### SUMMARY OF THE INVENTION

We have now discovered that the problem regarding the warpage of a semiconductor package still remains unsolved according to the conventional technique described in the above-mentioned patent publication. An object of the above-mentioned conventional technique is to reduce the difference in the amount of the thermal expansion between the heat spreader and an Si chip whose surface area is relatively small. In such a case, the stripe-like metallic body wherein Fe—Ni alloy and Cu metal are arranged in a stripe shape along one direction within the chip mounting surface may take effect. However, when such a heat spreader is attached to a package substrate whose surface area is wider than that of the Si chip, stresses along the one direction caused by the difference in the amount of the thermal expansion can not be neglected. Therefore, even when the heat spreader described in the above-explained patent publication is employed, the problem that the warpage of the package substrate appears along the one direction remains unsolved.

According to the present invention, a semiconductor device has a package substrate, and a heat spreader having a first surface attached to the package substrate. The heat spreader has a lattice-shaped slit opening on at least the first surface.

Due to the lattice-shaped slit as configured, a difference in the amount of the thermal expansion between the package substrate and the heat spreader is absorbed. As a result, warpage of a semiconductor package can be suppressed. In other words, even when the package substrate and the heat spreader are attached to each other through the heat treatment, and then their temperatures return to the room temperature, the warpage of the semiconductor package is small.

### BRIEF DESCRIPTIN OF THE DRAWINGS

The above and other objects, advantages and features of the present invention will be more apparent from the following description taken in conjunction with the accompanying drawings, in which:

FIG. 1 is a cross-sectional view showing a semiconductor device having a heat spreader according to the related art;

FIG. 2 is a cross-sectional view showing a semiconductor device according to a first embodiment of the present invention;

FIG. 3 is a cross-sectional view showing a semiconductor device according to a second embodiment of the present invention;

FIG. 4A is a cross-sectional view showing a semiconductor device according to a third embodiment of the present invention;

FIG. 4B is a top view showing the semiconductor device according to the third embodiment of the present invention;

FIG. 5A is a cross-sectional view showing a semiconductor device according to a fourth embodiment of the present invention;

FIG. 5B is a top view showing the semiconductor device according to the fourth embodiment of the present invention;

FIG. 6A shows one step of a method of manufacturing the semiconductor device according to the first embodiment;

FIG. 6B shows one step of the method of manufacturing the semiconductor device according to the first embodiment;

FIG. 6C shows one step of the method of manufacturing the semiconductor device according to the first embodiment;

FIG. 6D shows one step of the method of manufacturing the semiconductor device according to the first embodiment; and

FIG. 6E shows one step of the method of manufacturing the semiconductor device according to the first embodiment.

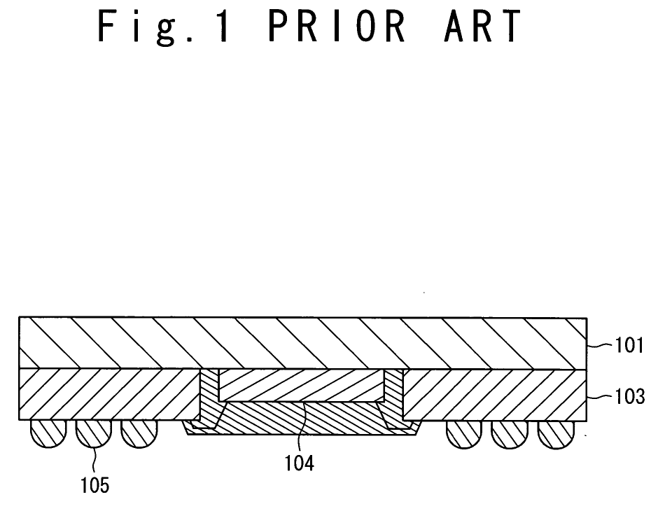

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

### First Embodiment

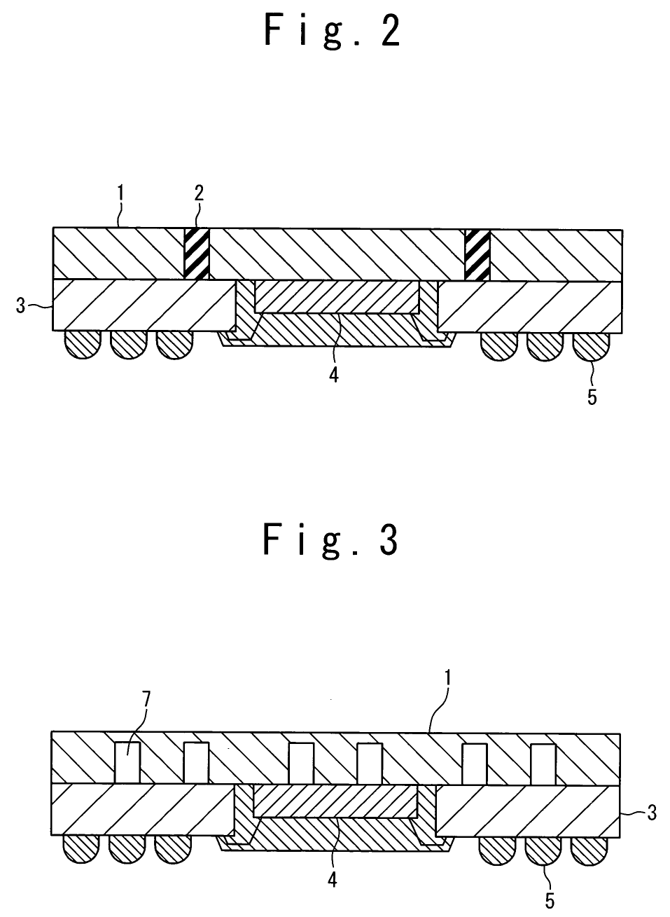

A semiconductor device according to a first embodiment of the present invention will be described below with reference to FIG. 2.

FIG. 2 is a cross-sectional view showing a structure of the semiconductor device. The semiconductor device has a package substrate 3.

A semiconductor chip 4 is accommodated in the package substrate 3, and an external terminal 5 such as a soldering ball is formed on a surface of the package substrate 3. Also, the semiconductor device has a heat spreader 1 attached to the package substrate 3 with an adhesive sheet. More specifically, a first surface of the heat spreader 1 is attached to the package substrate 3.

As shown in FIG. 2, a slit 2 is formed in the heat spreader 1. The slit 2 extends in a direction normal to a page surface. More specifically, the slit 2 has a lattice-shape when viewed from above, as will be described later. Also, the lattice-shaped slit 2 penetrates through the heat spreader 1 along the thickness direction. In other words, the lattice-shaped slit 2 opens on the first surface of the heat spreader 1 and a second surface opposite to the first surface. As a result, the heat spreader 1 is divided into a plurality of blocks. Thus, a difference in the amount of thermal expansion between the heat spreader 1 and the package substrate 3 is absorbed by the lattice-shaped slit 2. Therefore, warpage of the package substrate 3 and the semiconductor package can be suppressed and reduced.

The lattice-shaped slit 2 may be filled with a thermal conductive material having a good thermal conductivity. The elasticity of the thermal conductive material is higher than that of the heat spreader 1. When a width of the slit 2 is changed due to the difference in the thermal expansion coefficient between the heat spreader 1 and the package substrate 3, a width of the thermal conductive material is elastically changed in accordance with the change in the width of the slit 2. Moreover, when the lattice-shaped slit 2 is filled with the thermal conductive material, the workability in the manufacturing process and the sealing characteristics between the heat spreader 1 and the package substrate 3 can be secured.

### Second Embodiment

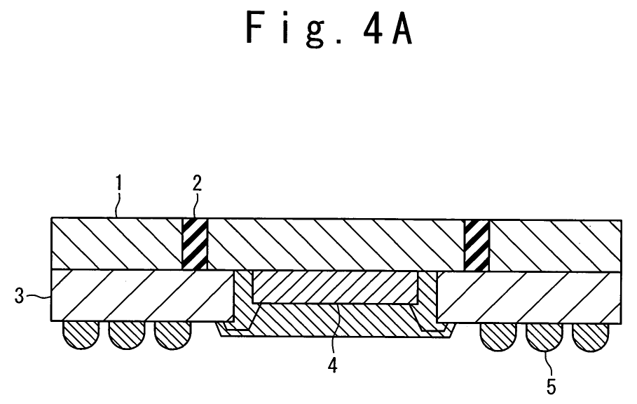

A semiconductor device according to a second embodiment of the present invention will be described below with reference to FIG. 3. FIG. 3 is a cross-sectional view showing a structure of the semiconductor device. In the present embodiment, a lattice-shaped slit 7 instead of the above-mentioned lattice-shaped slit 2 is formed in the heat spreader 1. Here, the lattice-shaped slit 7 does not penetrate through the heat spreader 1, as shown in FIG. 3. The lattice-shaped silt 7 opens only on the first surface of the heat spreader 1. In other words, the heat spreader 1 has apertures only on the first surface which is attached to the package substrate 3. The difference in the amount of thermal expansion between the heat spreader 1 and the package substrate 3 is absorbed by the lattice-shaped slit 7. Therefore, warpage of the package substrate 3 and the semiconductor package can be suppressed and reduced. It should be noted that the lattice-shaped slit 7 may be filled with a thermal conductive material, as in the first embodiment. The elasticity of the thermal conductive material is higher than that of the heat spreader 1.

### Third Embodiment

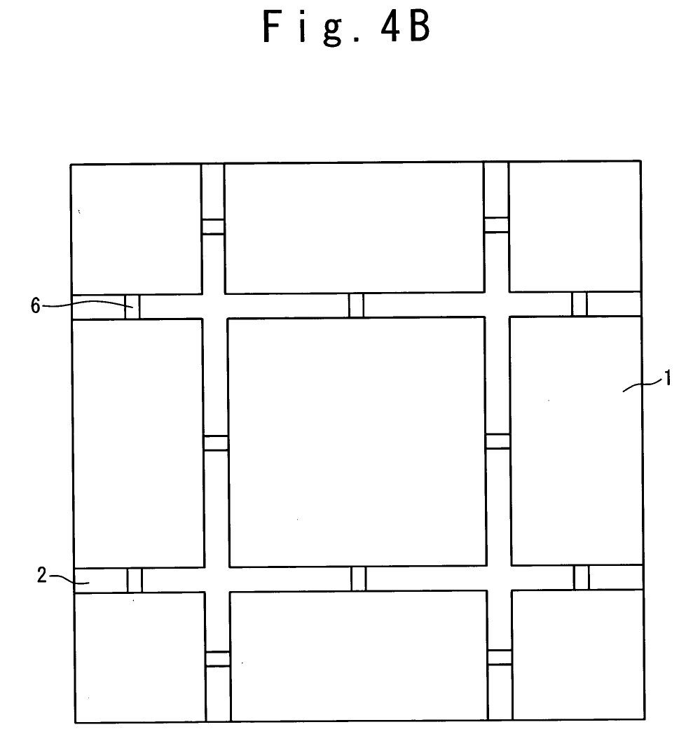

A semiconductor device according to a third embodiment of the present invention will be described below with reference to FIGS. 4A and 4B. FIG. 4A is a cross-sectional view showing a structure of the semiconductor device. FIG. 4B is a top view of the semiconductor device as viewed from the side of the heat spreader 1. As in the first embodiment, the lattice-shaped slit 2 penetrating through the heat spreader 1 is formed. The lattice-shaped slit 2 opens on the first surface and the second surface of the heat spreader 1, as shown in FIG. 4A. The heat spreader 1 is divided into a plurality of blocks due to the lattice-shaped slit 2, as shown in FIG. 4B.

A difference between the first embodiment and the present embodiment lies in that the plurality of blocks are coupled to one another by suspension pins 6. As shown in FIG. 4B, a block of the plurality of blocks is linked by suspension pins 6 to adjacent blocks. When the plurality of blocks are linked one another, handling of the heat spreader 1 becomes easy when it is mounted on the package substrate 3. The same thermal conductive material as in the first embodiment may be filled into the lattice-shaped slit 2. According to the semiconductor device as configured, the warpage of the package substrate 3 caused by the difference in the amount of the thermal expansion coefficient between the heat spreader 1 and the package substrate 3 can be reduced.

### Fourth Embodiment

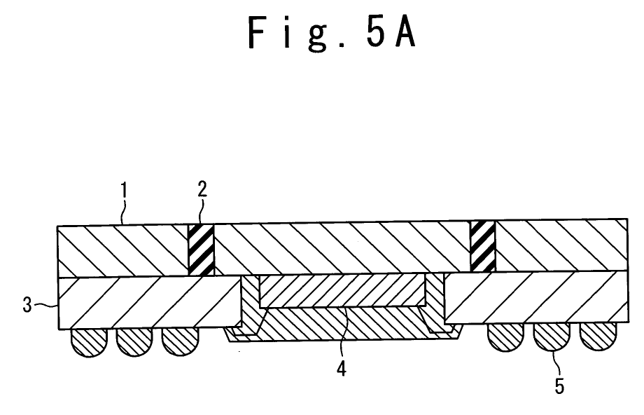

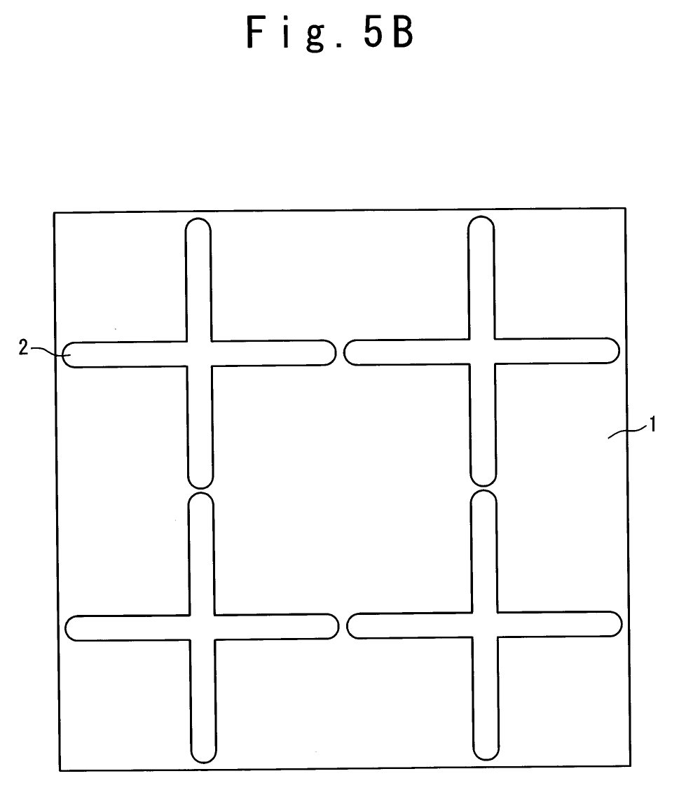

A semiconductor device according to a fourth embodiment of the present invention will be described below with reference to FIGS. 5A and 5B. FIG. 5A is a cross-sectional view showing a structure of the semiconductor device. FIG. 5B is a top view of the semiconductor device as viewed from the side of the heat spreader 1. As in the first embodiment, the lattice-shaped slit 2 penetrating through the heat spreader 1 is formed as shown in FIG. 5A. The heat spreader 1 is divided into a plurality of blocks due to the lattice-shaped slit 2, as shown in FIG. 5B.

A difference between the third embodiment and the present embodiment lies in that the plurality of blocks are coupled to one another by a member made of the same material as the heat spreader 1 instead of the suspension pins 6. As shown in FIG. 5B, a block of the plurality of blocks is linked to adjacent blocks by the member made of the same material as the heat spreader 1. Such a heat spreader 1 can be easily manufactured from one flat plate material. Also, when the plurality of blocks are linked one another, handling of the heat spreader 1 becomes easy when it is mounted on the package substrate 3. The same thermal conductive material as in the first embodiment may be filled into the lattice-shaped slit 2. According to the semiconductor device as configured, the warpage of the package substrate 3 caused by the difference in the amount of the thermal expansion coefficient between the heat spreader 1 and the package substrate 3 can be reduced.

### Method of Manufacturing

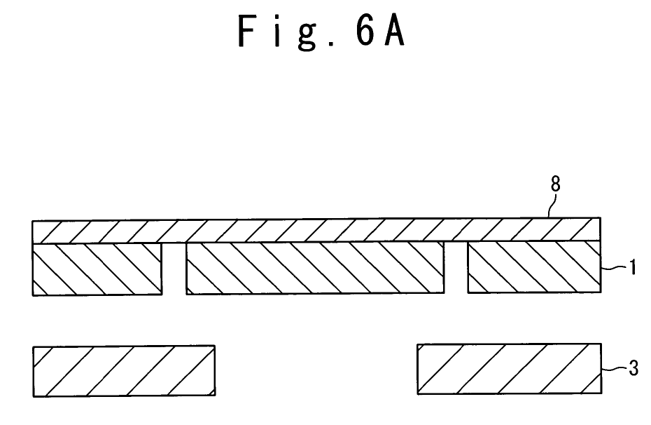

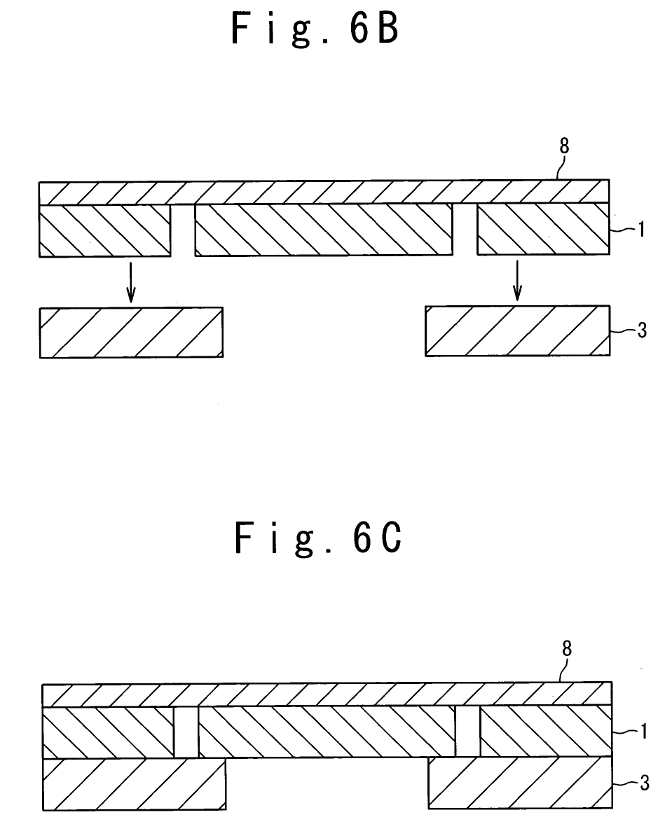

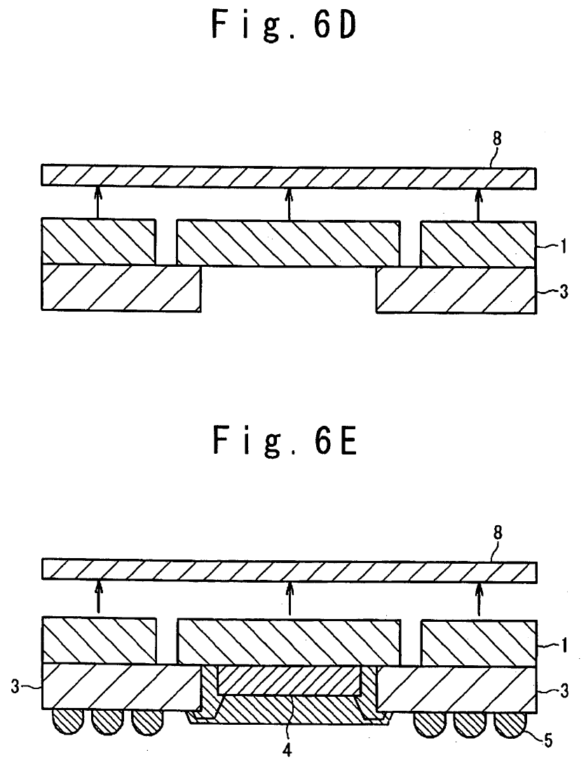

A method of manufacturing the semiconductor device according to the first embodiment of the present invention will now be described with reference to FIGS. 6A to 6E. First, a holding sheet 8 made of a resin or the like is attached to the heat spreader 1. Next, while the heat spreader 1 is being attached to the holding sheet 8, the heat spreader 1 is cut with intervals to form a lattice-shaped slit which penetrates through the heat spreader 1. As a result, the heat spreader 1 is divided into a plurality of blocks. Then, as shown in FIG. 6A, the heat spreader 1 is held by the holding sheet 8 in order to mount the heat spreader 1 on the package substrate 3. As the holding sheet 8, a plate-shaped resin, a plate-shaped glass, or a plate-shaped metal may be employed. Next, an adhesive sheet (not shown) is provisionally attached to either the package substrate 3 on which external terminals are provided or the heat spreader 1. In a case that the adhesive sheet is attached to the heat spreader 1, the adhesive sheet may be attached before the heat spreader 1 is divided into blocks, and thereafter the adhesive sheet may be cut together with the heat spreader 1. Next, both the heat spreader 1 which is held by the holding sheet 8 and the package substrate 3 are heated together with the adhesive sheet, and thereby the adhesive sheet is melted. Next, as shown in FIG. 6B, the heat spreader 1 is moved close to the package substrate 3. Then, as represented in FIG. 6C, the heat spreader 1 is attached to the package substrate 3 with the melted adhesive sheet. Next, as shown in FIG. 6D, the holding sheet 8 is detached from the heat spreader 1 by performing a proper heating treatment or the like. The holding sheet 8 may be detached from the heat spreader 1 after the semiconductor device is manufactured. Next, as shown in FIG. 6E, a semiconductor chip 4 is provided on the surface of the heat spreader 1 and the bonding is carried out.

According to the semiconductor device of the present invention, the warpage of the semiconductor package can be reduced and the yield of the semiconductor device can be improved, even in a case of a large package having multi-pins.

It should be noted that the holding sheet 8 is used when manufacturing the semiconductor device of the first embodiment, as explained above. However, when manufacturing the semiconductor devices of the second, third, and fourth embodiments, the holding sheet 8 is not necessary, because the heat spreader 1 is not divided into a plurality of blocks in the second embodiment and the plurality of blocks are linked one another in the third and the fourth embodiments. In such a case, the semiconductor device can be manufactured as follows. First, a slit is first formed in a heat spreader. Next, a surface of the heat spreader on which the slit opens is attached to a package substrate with an adhesive agent such as an adhesive sheet which is melted by a heat treatment. Next, a chip is provided on the surface of the heat spreader attached to the package substrate, and then the bonding is carried out. Thus, the semiconductor device can be manufactured.

It will be obvious to one skilled in the art that the present invention may be practiced in other embodiments that depart from the above-described specific details. The scope of the present invention, therefore, should be determined by the following claims.

1. A semiconductor device comprising:
a package substrate; and
a heat spreader having a first surface attached to said package substrate,
wherein said heat spreader has a lattice-shaped slit opening on at least said first surface.

2. The semiconductor device according to claim 1,
wherein said lattice-shaped slit penetrates through said heat spreader such that said heat spreader is divided into a plurality of blocks.

3. The semiconductor device according to claim 2,
wherein a block of said plurality of blocks is linked by a pin to another block of said plurality of blocks.

4. The semiconductor device according to claim 2,
wherein a block of said plurality of blocks is linked by a member made of a same material as said heat spreader to another block of said plurality of blocks.

5. The semiconductor device according to claim 1,
wherein said lattice-shaped slit is filled with a material whose elasticity is higher than elasticity of said heat spreader.

6. The semiconductor device according to claim 2,
wherein said lattice-shaped slit is filled with a material whose elasticity is higher than elasticity of said heat spreader.

7. The semiconductor device according to claim 3,
wherein said lattice-shaped slit is filled with a material whose elasticity is higher than elasticity of said heat spreader.

8. The semiconductor device according to claim 4,
wherein said lattice-shaped slit is filled with a material whose elasticity is higher than elasticity of said heat spreader.

9. The semiconductor device according to claim 1,
wherein said lattice-shaped slit is filled with a thermal conductive material.

10. The semiconductor device according to claim 2,
wherein said lattice-shaped slit is filled with a thermal conductive material.

11. The semiconductor device according to claim 3,
wherein said lattice-shaped slit is filled with a thermal conductive material.

12. The semiconductor device according to claim 4,
wherein said lattice-shaped slit is filled with a thermal conductive material.

13. The semiconductor device according to claim 5,
wherein said lattice-shaped slit is filled with a thermal conductive material.

14. The semiconductor device according to claim 6,
wherein said lattice-shaped slit is filled with a thermal conductive material.

15. The semiconductor device according to claim 7,
wherein said lattice-shaped slit is filled with a thermal conductive material.

16. The semiconductor device according to claim 8,
wherein said lattice-shaped slit is filled with a thermal conductive material.
